(19) United States
(12) Patent Application Publication
(10) Pub. No.: US 2025/0226640 A1
(43) Pub. Date: Jul. 10, 2025

(54) SURFACE EMITTING LASER AND METHOD FOR MANUFACTURING THE SAME

(71) Applicant: KABUSHIKI KAISHA TOSHIBA, Tokyo (JP)

(72) Inventors: Rei HASHIMOTO, Edogawa Tokyo (JP); Shinji SAITO, Yokohama Kanagawa (JP); Tsutomu KAKUNO, Fujisawa Kanagawa (JP); Kei KANEKO, Yokohama Kanagawa (JP)

(21) Appl. No.: 18/984,731

(22) Filed: Dec. 17, 2024

(30) Foreign Application Priority Data
Jan. 5, 2024 (JP) 2024-000680

(51) Int. Cl. H01S 5/11; H01S 5/183; H01S 5/34

(52) U.S. Cl. CPC H01S 5/11; H01S 5/18305; H01S 5/3402

(57) ABSTRACT

According to one embodiment, a surface emitting laser includes first and second electrodes, a light emitting layer, and first and second crystal layers. The light emitting layer is provided between the first electrode and the second electrode. The first crystal layer is provided between the light emitting layer and the second electrode. The first crystal layer includes a first partial region and a second partial region. The second crystal layer includes a plurality of structures. At least a part of the plurality of structures is arranged in a second direction crossing a first direction from the first electrode to the second electrode. The plurality of structures are provided between the light emitting layer and the first partial region in the first direction. At least a part of the second partial region is provided between the plurality of structures in the second direction.

### CROSS-REFERENCE TO RELATED APPLICATIONS

This application is based upon and claims the benefit of priority from Japanese Patent Application No. 2024-000680, filed on Jan. 5, 2024; the entire contents of which are incorporated herein by reference.

### FIELD

Embodiments described herein relate generally to a surface emitting laser and method for manufacturing the same.

### BACKGROUND

For example, optical elements such as photonic crystals are used in surface emitting lasers. It is desired to improve the characteristics of surface emitting lasers.

### BRIEF DESCRIPTION OF THE DRAWINGS

FIG. 1 is a schematic cross-sectional view illustrating a surface emitting laser according to a first embodiment;

FIG. 2 is a schematic plan view illustrating a part of the surface emitting laser according to the first embodiment;

FIG. 3 is a schematic cross-sectional view illustrating a surface emitting laser according to the first embodiment;

FIG. 4 is a schematic cross-sectional view illustrating a surface emitting laser according to the first embodiment;

FIG. 5 is a schematic cross-sectional view illustrating a method for manufacturing a surface emitting laser according to the second embodiment;

FIG. 6 is a schematic cross-sectional view illustrating the method for manufacturing the surface emitting laser according to the second embodiment;

FIG. 7 is a schematic cross-sectional view illustrating the method for manufacturing the surface emitting laser according to the second embodiment;

FIG. 8 is a schematic cross-sectional view illustrating the method for manufacturing the surface emitting laser according to the second embodiment;

FIG. 9 is a schematic cross-sectional view illustrating the method for manufacturing the surface emitting laser according to the second embodiment; and

FIG. 10 is a schematic cross-sectional view illustrating the method for manufacturing the surface emitting laser according to the second embodiment.

### DETAILED DESCRIPTION

According to one embodiment, a surface emitting laser includes a first electrode, a second electrode, a light emitting layer, a first crystal layer, and a second crystal layer. The light emitting layer is provided between the first electrode and the second electrode. The first crystal layer is provided between the light emitting layer and the second electrode. The first crystal layer includes a first partial region and a second partial region. The second crystal layer includes a plurality of structures. At least a part of the plurality of structures is arranged in a second direction crossing a first direction from the first electrode to the second electrode. The plurality of structures are provided between the light emitting layer and the first partial region in the first direction. At least a part of the second partial region is provided between the plurality of structures in the second direction. One of the plurality of structures includes a first region and a second region provided between the first region and the first partial region. A concentration of a first element in the second partial region is higher than a concentration of the first element in the second region, or the second partial region includes the first element and the second region does not include the first element. A refractive index of the first region is higher than a refractive index of the second partial region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

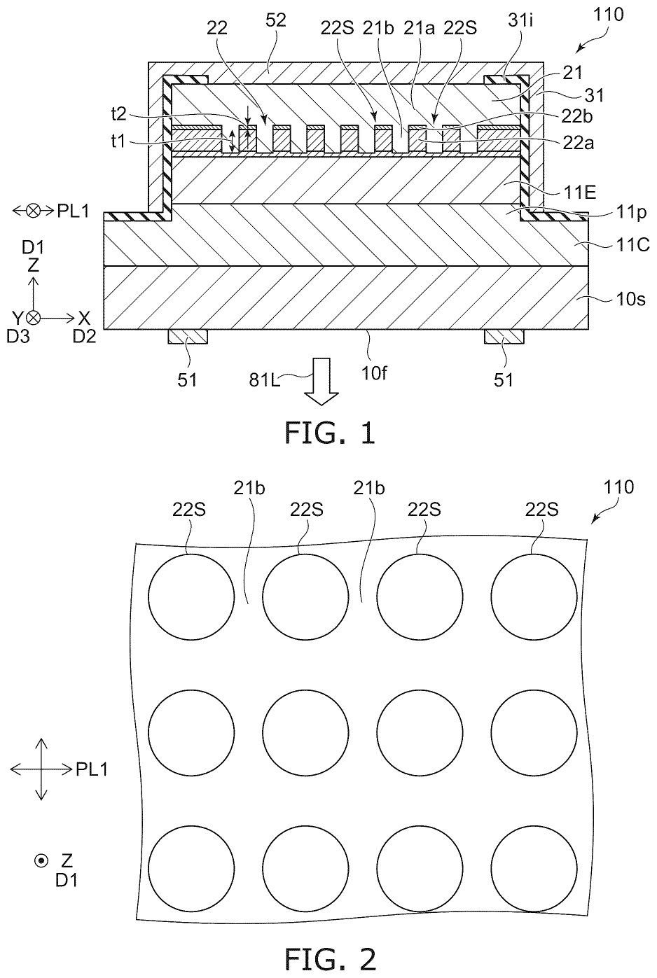

FIG. 1 is a schematic cross-sectional view illustrating a surface emitting laser according to a first embodiment.

FIG. 2 is a schematic plan view illustrating a part of the surface emitting laser according to the first embodiment.

As shown in FIG. 1, the surface emitting laser 110 according to the embodiment includes a first electrode 51, a second electrode 52, a light emitting layer 11E, a first crystal layer 21, and a second crystal layer 22.

The light emitting layer 11E is provided between the first electrode 51 and the second electrode 52. The first crystal layer 21 is provided between the light emitting layer 11E and the second electrode 52. The light emitting layer 11E is, for example, an active layer. The first crystal layer 21 includes a first partial region 21a and a second partial region 21b.

A first direction D1 from the first electrode 51 to the second electrode 52 is defined as a Z-axis direction. One direction perpendicular to the Z-axis direction is defined as an X-axis direction. A direction perpendicular to the Z-axis direction and the X-axis direction is defined as a Y-axis direction.

The second crystal layer 22 includes a plurality of structures 22S. At least a part of the plurality of structures 22S are arranged up in a second direction D2 crossing the first direction D1.

FIG. 2 illustrates the plurality of structures 22S. As shown in FIG. 2, the plurality of structures 22S may be two-dimensionally arranged in a first plane PL1 crossing the first direction D1. The plurality of structures 22S may be arranged along a third direction D3. The third direction D3 crosses a plane including the first direction D1 and the second direction D2. The planar shape of the plurality of structures 22S is arbitrary. The planar shape may be, for example, a polygon. At least a part of the plurality of structures 22S may be arranged at a first pitch. The pitch of the plurality of structures 22S in one direction may be different from the pitch of the plurality of structures 22S in another direction.

As shown in FIG. 1, the plurality of structures 22S are provided between the light emitting layer 11E and the first partial region 21a in the first direction D1. As shown in FIG. 1, at least a part of the second partial region 21b is provided between the plurality of structures 22S in the second direction D2. As shown in FIG. 2, the second partial region 21b may be provided between the plurality of structures 22S in the first plane PL1.

As shown in FIG. 1, one of the plurality of structures 22S includes a first region 22a and a second region 22b. The second region 22b is provided between the first region 22a and the first partial region 21a.

In the embodiment, the first crystal layer 21 and the second crystal layer 22 are, for example, semiconductors.

In the embodiment, a concentration of a first element in the second partial region 21b is higher than a concentration of the first element in the second region 22b. Alternatively, the second partial region 21b includes the first element, and the second region 22b does not include the first element. The first element is, for example, an impurity.

A refractive index of the first region 22a is higher than a refractive index of the second partial region 21b. The first region 22a and the second partial region 21b having different refractive indexes are arranged periodically. For example, a structure including the first region 22a and the second partial region 21b functions as a photonic crystal layer.

For example, light (electromagnetic waves) is emitted from the light emitting layer 11E by a current based on a voltage applied between the first electrode 51 and the second electrode 52. For example, light enters a photonic crystal layer, and the traveling direction of the light changes. The light whose traveling direction has been changed travels, for example, along a direction crossing the light emitting layer 11E. For example, light 81L (electromagnetic waves) including a component along the Z-axis direction is emitted to the outside. The light flux of The light 81L has a planar shape. The wavelength of the light 81L may be, for example, not less than 3 μm and not more than 10 μm. Hereinafter, electromagnetic waves with a wavelength not less than 3 μm and not more than 10 μm will also be referred to as “light.”

In the photonic crystal layer, it is preferable that the difference between the refractive index of the first region 22a and the refractive index of the second partial region 21b is large. Thereby, the traveling direction of light can be controlled with higher efficiency.

In the embodiment, the photonic crystal layer is provided between the light emitting layer 11E and the second electrode 52. The current flows to the light emitting layer 11E through the first crystal layer 21 and the second crystal layer 22. In the embodiment, the concentration of the first element in the second partial region 21b is higher than the concentration of the first 25 element in the second region 22b. Alternatively, the second partial region 21b includes the first element, and the second region 22b does not include the first element. Thereby, the current flows mainly through the second partial region 21b. On the other hand, the current hardly flows through the second region 22b and also hardly flows into the first region 22a. The current path is controlled. For example, current confinement occurs.

The effective refractive index of the second partial region 21b decreases due to carriers flowing in the second partial region 21b where current flows mainly. Thereby, the difference between the refractive index of the second partial region 21b and the refractive index of the first region 22a when current is flowing increases. Thereby, it becomes possible to control light with higher efficiency. According to the embodiment, a surface emitting laser whose characteristics can be improved can be provided.

For example, when a semiconductor crystal is doped with a first element such as Si when no current (carrier) flows, the refractive index of the semiconductor crystal increases. On the other hand, when carriers flow into the semiconductor crystal doped with the first element, the refractive index decreases due to the flow of carriers. In the embodiment, a high-density current flows through the second partial region 21b due to current confinement. As a result, the effect of lowering the refractive index due to carriers exceeds the effect of increasing refractive index due to doping with the first element. As a result, the effective refractive index decreases. In the embodiment, the effect of lowering the refractive index due to carrier flow is effectively utilized.

For example, the conductivity of the second region 22b where the concentration of the first element is low is lower than the conductivity of the second partial region 21b where the concentration of the first element is high. The second region 22b functions, for example, as a current passage suppression layer. The second region 22b may function as a current blocking layer, for example.

In one example, the first crystal layer 21 includes InP. The first element includes at least one selected from the group consisting of Si and Fe. The concentration of the first element in the first crystal layer 21 (for example, the second partial region 21b) may be not less than 5 times and not more than 1000 times the concentration of the first element in the second region 22b. The concentration of the first element in the first crystal layer 21 (for example, the second partial region 21b) may be 10,000 times or less the concentration of the first element in the second region 22b.

In one example, the concentration of the first element in the first crystal layer 21 (for example, the second partial region 21b) is, for example, not less than 5×10¹⁶ cm⁻³ and not more than 1×10¹⁹ cm⁻³. If the concentration of the first element in the first crystal layer 21 is excessively high, light absorption tends to increase.

For example, the concentration of the first element in the second region 22b may be less than 1×10¹⁶ cm⁻³.

In the embodiment, the first region 22a may include, for example, InGaAs. The second region 22b includes InP. The second region 22b may include, for example, undoped InP. For example, the electrical conductivity of the second region 22b is lower than that of the second partial region 21b. The second region 22b is, for example, a high resistance region. The second partial region 21b is, for example, a low resistance region.

In the embodiment, the concentration of the first element in the first region 22a may be higher than the concentration of the first element in the second region 22b. Alternatively, the first region 22a may include the first element, and the second region 22b may not include the first element. As already explained, it is difficult for current to flow through the first region 22a. Therefore, even when the first region 22a includes the first element, the refractive index does not substantially decrease due to carriers in the first region 22a. Therefore, the refractive index is effectively increased due to the first region 22a including the first element. When the first region 22a (for example, InGaAs) includes the first element (for example, Si), it is easier to obtain a high refractive index in the first region 22a (for example, InGaAs) compared to a case where the first region 22a (for example, InGaAs) does not include the first element. Thereby, the difference in refractive index between the first region 22a and the second partial region 21b can be increased.

As shown in FIG. 1, a thickness of the first region 22a along the first direction D1 is defined as a first thickness t1. A thickness of the second region 22b along the first direction D1 is defined as a second thickness t2. In the embodiment, the second thickness t2 is preferably thinner than the first thickness t1. By the first thickness t1 being thick, light can be controlled with high efficiency.

In one example, the second thickness t2 may be not less than 100 nm and not more than 300 nm. When the second thickness t2 is excessively thin, it becomes difficult to control the current. When the second thickness t2 is excessively thick, it will be difficult to obtain high crystallinity.

In one example, the first thickness t1 may be not less than 500 nm and not more than 1500 nm. When the first thickness t1 is excessively thin, it becomes difficult to control light. When the first thickness t1 is excessively thick, it becomes difficult to obtain high crystallinity.

As shown in FIG. 1, the surface emitting laser 110 may further include a first cladding layer 11C. The first cladding layer 11C is provided between the first electrode 51 and the light emitting layer 11E. For example, the light emitting layer 11E is provided between a part 11p of the first cladding layer 11C and the second crystal layer 22. For example, a ridge structure is obtained by the part 11p of the first cladding layer 11C. In one example, the thickness of the first cladding layer 11C may be not less than 3 μm and not more than 5 μm.

For example, the refractive index of the first cladding layer 11C is lower than the refractive index of the light emitting layer 11E. The first cladding layer 11C includes, for example, InP. The first crystal layer 21 may function as a second cladding layer, for example.

The light emitting layer 11E includes an AlInAs film and an InGaAs film. These films are provided alternately along the first direction D1. For example, the thickness of the light emitting layer 11E is not less than 1 μm and not more than 2 μm. The light emitting layer 11E emits light due to inter-subband transition. The surface emitting laser 110 may be, for example, a surface emitting quantum cascade laser (QCL). The wavelength of the light 81L may be, for example, not less than 3 μm and not more than 10 μm.

As shown in FIG. 1, the surface emitting laser 110 may include a base 10s. The base 10s is provided between the first electrode 51 and the first cladding layer 11C. The base 10s may be, for example, an InP substrate. The light 81L is emitted from one surface of the base 10s.

As shown in FIG. 1, an insulating film 31i may be provided between the second electrode 52 and a part of the first crystal layer 21. The insulating film 31i may include, for example, silicon oxide. The surface emitting laser 110 may include a reflective film 31. A direction from the light emitting layer 11E to the reflective film 31, a direction from the first crystal layer 21 to the reflective film 31, and a direction from the second crystal layer 22 to the reflective film 31 cross the first direction D1. A part of the insulating film 31i may be is provided between the light emitting layer 11E and the reflective film 31, between the first crystal layer 21 and the reflective film 31, and between the second crystal layer 22 and the reflective film 31.

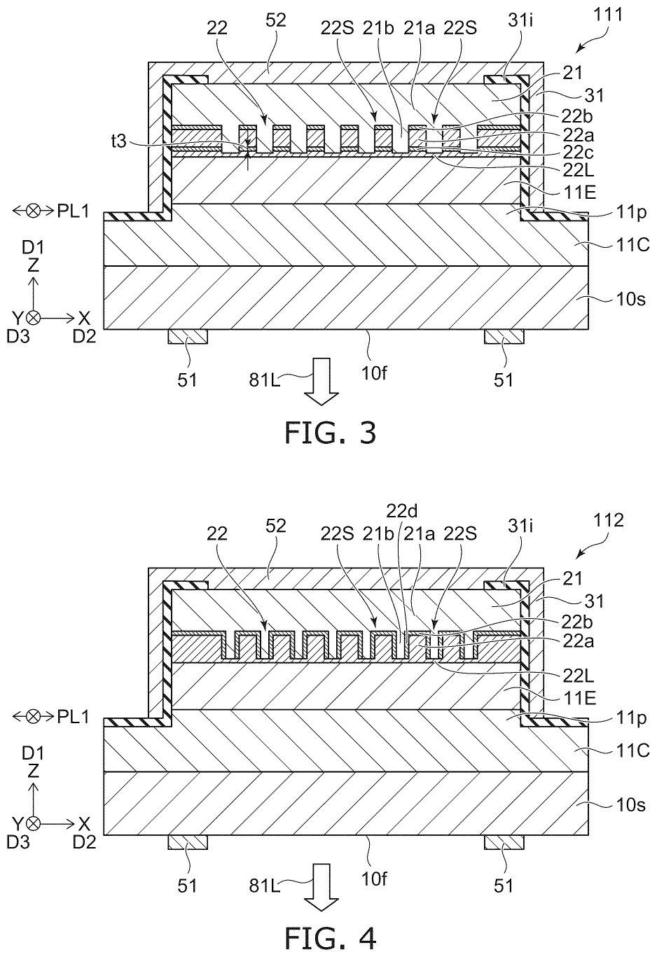

FIG. 3 is a schematic cross-sectional view illustrating a surface emitting laser according to the first embodiment.

As shown in FIG. 3, in a surface emitting laser 111 according to the embodiment, one of the plurality of structures 22S further includes a third region 22c. In this example, the second crystal layer 22 further includes a first planar region 22L. The configuration of the surface emitting laser 111 except for these may be the same as the configuration of the surface emitting laser 110.

The first region 22a is provided between a part of the first planar region 22L and the second region 22b. The second partial region 21b is provided between another part of the first planar region 22L and the second electrode 52. The concentration of the first element in the first planar region 22L may be higher than the concentration of the first element in the second region 22b. Alternatively, the first planar region 22L includes the first element, and the second region 22b does not include the first element. The first planar region 22L includes InP including the first element (for example, Si).

The third region 22c is provided between the first planar region 22L and the first region 22a. For example, the concentration of the first element in the third region 22c may be lower than the concentration of the first element in the second partial region 21b. Alternatively, the second partial region 21b includes the first element, and the third region 22c does not include the first element. The third region 22c includes, for example, undoped InP.

For example, the concentration of the first element in the third region 22c may be lower than the concentration of the first element in the first region 22a. Alternatively, the first region 22a may include the first element, and the third region 22c may not include the first element. The third region 22c is, for example, a high resistance region.

By providing the third region 22c, the current flows more efficiently through the second partial region 21b. A large difference in high refractive indexes can be stably obtained.

As shown in FIG. 3, a thickness of the third region 22c along the first direction D1 is defined as a third thickness t3. The third thickness t3 may be, for example, not less than 100 nm and not more than 300 nm.

The first planar region 22L may function, for example, as an etching stopper when processing the plurality of structures 22S. The first planar region 22L may have a function of spreading the current flowing through the second partial region 21b, for example.

FIG. 4 is a schematic cross-sectional view illustrating a surface emitting laser according to the first embodiment.

As shown in FIG. 4, in a surface emitting laser 112 according to the embodiment, one of the plurality of structures 22S further includes a fourth region 22d. The configuration of the surface emitting laser 112 except for this may be the same as the configuration of the surface emitting laser 110.

The fourth region 22d is provided between the second partial region 21b and the first region 22a in the second direction D2. The fourth region 22d may be provided between the second partial region 21b and the first region 22a in the first plane PL1. The concentration of the first element in the second partial region 21b is higher than the concentration of the first element in the fourth region 22d. Alternatively, the second partial region 21b includes the first element, and the fourth region 22d does not include the first element. By providing such a fourth region 22d, the current flows more efficiently and in a concentrated manner through the second partial region 21b. A large difference in refractive indexes can be efficiently obtained.

The fourth region 22d may include, for example, undoped InP. As shown in FIG. 4, in this example, the fourth region 22d is continuous with the second region 22b.

### Second Embodiment

The second embodiment relates to a method of manufacturing a surface emitting laser.

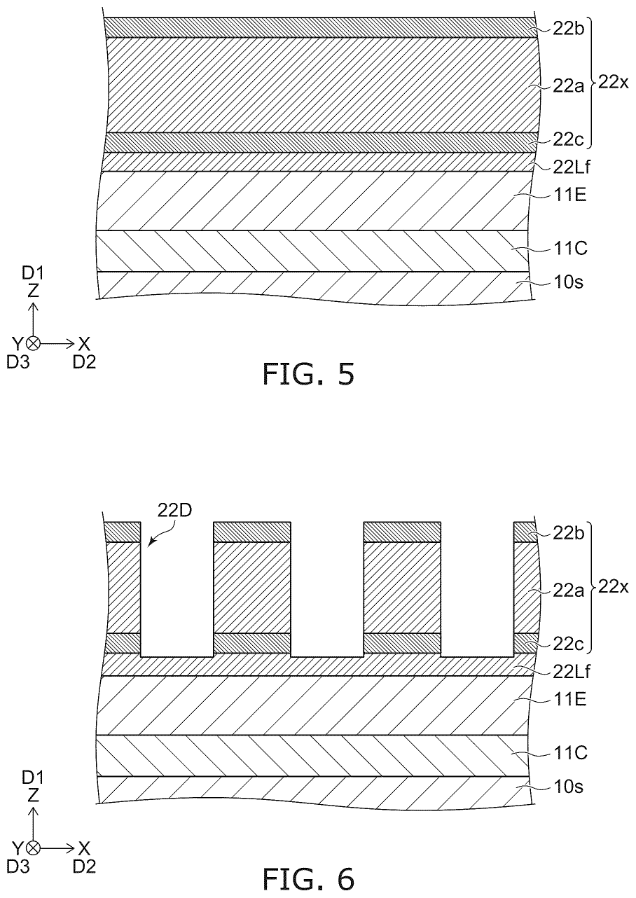

FIGS. 5 to 7 are schematic cross-sectional views illustrating a method for manufacturing a surface emitting laser according to the second embodiment.

As shown in FIG. 5, a workpiece 22x is formed on the first planar region film 22Lf provided on the light emitting layer 11E. The workpiece 22x includes the first region 22a and the second region 22b above the first region 22a. The light emitting layer 11E may be provided on the first cladding layer 11C provided on the base 10s. The workpiece 22x may be formed, for example, by epitaxial growth. The first planar region film 22Lf becomes the first planar region 22L.

As shown in FIG. 6, a part of the workpiece 22x is removed to expose a part of the first planar region film 22Lf, thereby forming a recess 22D.

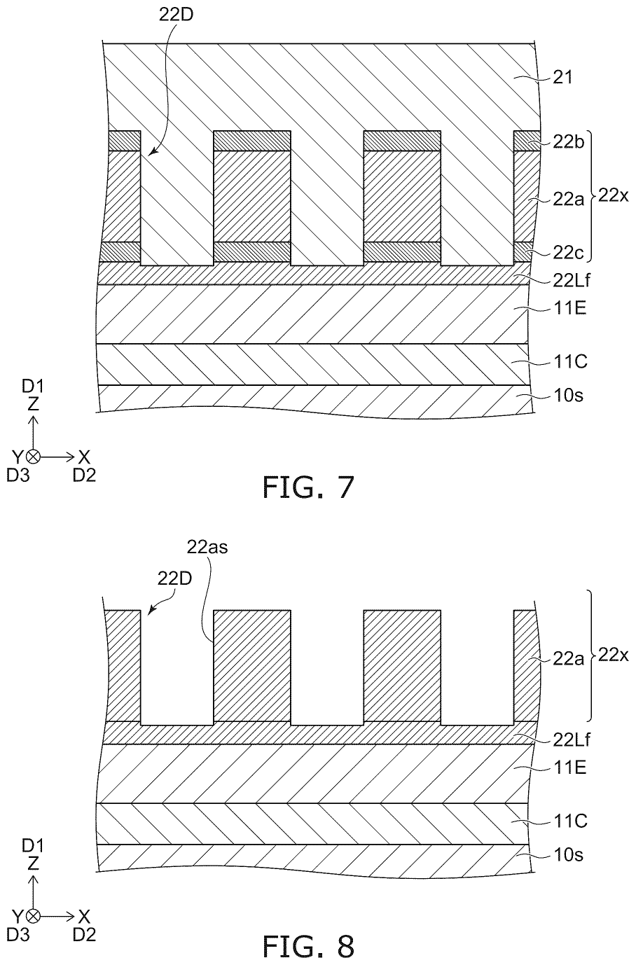

As shown in FIG. 7, the first crystal layer 21 is formed in the recess 22D and on the second region 22b.

In the embodiment, the concentration of the first element in the first crystal layer 21 is higher than the concentration of the first element in the second region 22b. Alternatively, the first crystal layer 21 includes the first element, and the second region 22b does not include the first element. The refractive index of the first region 22a is higher than the refractive index of the first crystal layer 21.

After the above processing, by forming the ridge portion, forming the insulating film 31i, forming the second electrode 52, and forming the first electrode 51, for example, the surface emitting laser 110 or the surface emitting laser 111 is obtained. By the above manufacturing method, a surface emitting laser whose characteristics can be improved can be efficiently manufactured.

In this example, the first crystal layer 21 includes InP. The first element includes, for example, at least one selected from the group consisting of Si and Fe.

As shown in FIG. 5, the workpiece 22x may further include the third region 22c. The third region 22c is provided between the first planar region film 22Lf and the first region 22a. In one example, the concentration of the first element in the third region 22c is higher than the concentration of the first element in the first crystal layer 21. Alternatively, the first crystal layer 21 includes the first element, and the third region 22c does not include the first element.

FIGS. 8 to 10 are schematic cross-sectional views illustrating a method for manufacturing a surface emitting laser according to the second embodiment.

As shown in FIG. 8, a workpiece 22x including the first region 22a is formed on the first planar region film 22Lf provided on the light emitting layer 11E. Furthermore, a part of the workpiece 22x is removed to form a recess 22D. In the recess 22D, a part of the first planar region film 22Lf and the side face 22as of the first region 22a are exposed.

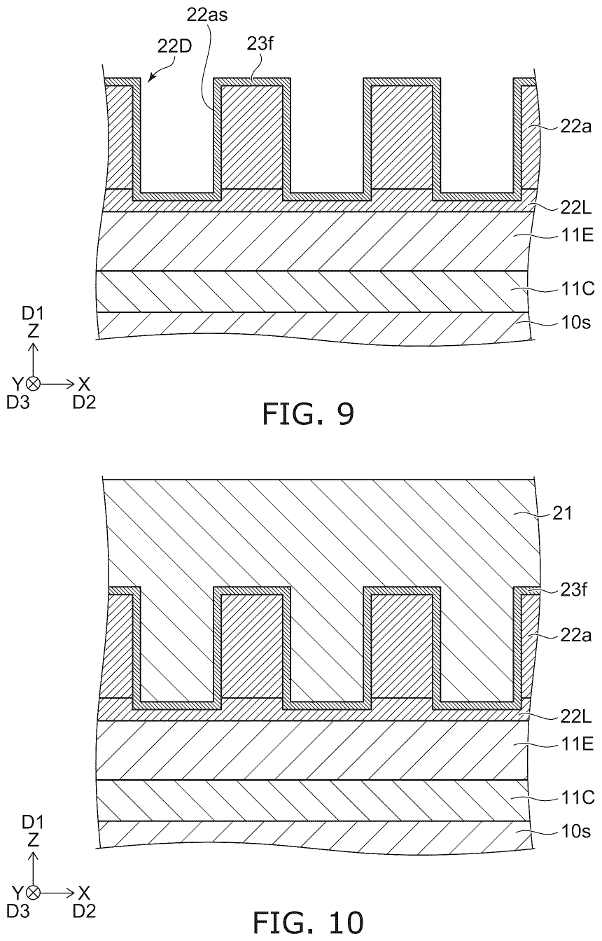

As shown in FIG. 9, a crystal film 23f is formed on a part of the first planar region film 22Lf (first planar region 22L), the side face 22as of the first region 22a, and the first region 22a being remained. At least a part of the crystal film 23f becomes, for example, the fourth region 22d.

As shown in FIG. 10, the first crystal layer 21 is formed in the remaining space of the recess 22D. The first crystal layer 21 may be formed on the crystal film 23f. The concentration of the first element in the first crystal layer 21 is higher than the concentration of the first element in the crystal film 23f. Alternatively, the first crystal layer 21 includes the first element, and the crystal film 23f does not include the first element. The refractive index of the first region 22a is higher than the refractive index of the first crystal layer 21.

After the above processing, the surface emitting laser 112, for example, is obtained by forming the ridge portion, forming the insulating film 31i, forming the second electrode 52, and forming the first electrode 51. By the above manufacturing method, a surface emitting laser whose characteristics can be improved can be efficiently manufactured.

In the above example, the first crystal layer 21 includes InP. The first element includes at least one selected from the group consisting of Si and Fe. The crystal film 23f includes InP. The embodiments may include the following Technical proposals:

### (Technical Proposal 1)

A surface emitting laser, comprising:
a first electrode;
a second electrode;
a light emitting layer provided between the first electrode and the second electrode;
a first crystal layer provided between the light emitting layer and the second electrode, the first crystal layer including a first partial region and a second partial region; and
a second crystal layer including a plurality of structures, at least a part of the plurality of structures being arranged in a second direction crossing a first direction from the first electrode to the second electrode, the plurality of structures being provided between the light emitting layer and the first partial region in the first direction, at least a part of the second partial region being provided between the plurality of structures in the second direction, one of the plurality of structures includes a first region and a second region provided between the first region and the first partial region, a concentration of a first element in the second partial region being higher than a concentration of the first element in the second region, or the second partial region including the first element and the second region not including the first element, a refractive index of the first region being higher than a refractive index of the second partial region.

### (Technical Proposal 2)

The surface emitting laser according to Technical proposal 1, wherein
the first crystal layer includes InP, and
the first element includes at least one selected from the group consisting of Si and Fe.

### (Technical Proposal 3)

The surface emitting laser according to Technical proposal 2, wherein
the first region includes InGaAs, and
the second region includes InP.

### (Technical Proposal 4)

The surface emitting laser according to any one of Technical proposals 1-3, wherein
an electrical conductivity of the second region is lower than an electrical conductivity of the second partial region.

### (Technical Proposal 5)

The surface emitting laser according to any one of Technical proposals 1-4, wherein
the second crystal layer further includes a first planar region,
the first region is provided between a part of the first planar region and the second region, and
the second partial region is provided between another part of the first planar region and the second electrode.

### (Technical Proposal 6)

The surface emitting laser according to Technical proposal 5, wherein
a concentration of the first element in the first planar region is higher than the concentration of the first element in the second region, or the first planar region includes the first element and the second region does not include the first element.

### (Technical Proposal 7)

The surface emitting laser according to Technical proposal 5 or 6, wherein
the one of the plurality of structures further includes a third region,
the third region is provided between the first planar region and the first region,
a concentration of the first element in the third region is lower than the concentration of the first element in the second partial region, or the second partial region includes the first element and the third region does not include the first element.

### (Technical Proposal 8)

The surface emitting laser according to Technical proposal 7, wherein
a third thickness of the third region along the first direction is not less than 100 nm and not more than 300 nm.

### (Technical Proposal 9)

The surface emitting laser according to any one of Technical proposals 1-8, wherein
a concentration of the first element in the first region is higher than the concentration of the first element in the second region or the first region includes the first element and the second region does not include the first element.

### (Technical Proposal 10)

The surface emitting laser according to any one of Technical proposals 1-9, wherein
a second thickness of the second region along the first direction is thinner than a first thickness of the first region along the first direction.

### (Technical Proposal 11)

The surface emitting laser according to Technical proposal 10, wherein
the second thickness is not less than 100 nm and not more than 300 nm, and
the first thickness is not less than 500 nm and not more than 1500 nm.

### (Technical Proposal 12)

The surface emitting laser according to any one of Technical proposals 1-11, wherein
the one of the plurality of structures further includes a fourth region,
the fourth region is provided between the second partial region and the first region in the second direction,
the concentration of the first element in the second partial region is higher than a concentration of the first element in the fourth region, or the second partial region includes the first element and the fourth region does not include the first element.

### (Technical Proposal 13)

The surface emitting laser according to Technical proposal 12, wherein
the fourth region is continuous with the second region.

### (Technical Proposal 14)

The surface emitting laser according to any one of Technical proposals 1-13, further comprising:
a first cladding layer provided between the first electrode and the light emitting layer,
the light emitting layer being provided between a part of the first cladding layer and the second crystal layer.

### (Technical Proposal 15)

The surface emitting laser according to any one of Technical proposals 1-14, wherein
the light-emitting layer emits light by inter-subband transition.

### (Technical Proposal 16)

A method for manufacturing a surface emitting laser, the method comprising:
forming a workpiece on a first planar region film provided on a light emitting layer, the workpiece including a first region and a second region above the first region;
removing a part of the workpiece to expose a part of the first planar region film to form a recess; and
forming a first crystal layer in the recess and on the second region,
a concentration of the first element in the first crystal layer being higher than a concentration of the first element in the second region, or the first crystal layer including the first element and the second region not including the first element, and
a refractive index of the first region being higher than a refractive index of the first crystal layer.

### (Technical Proposal 17)

The method for manufacturing the surface emitting laser according to Technical proposal 16, wherein
the first crystal layer includes InP, and
the first element includes at least one selected from the group consisting of Si and Fe.

### (Technical Proposal 18)

The method for manufacturing the surface emitting laser according to Technical proposal 16 or 17, wherein
the workpiece further includes a third region provided between the first planar region film and the first region, and
a concentration of the first element in the third region is higher than the concentration of the first element in the first crystal layer, or the first crystal layer includes the first element and the third region does not include the first element.

### (Technical Proposal 19)

A method for manufacturing a surface emitting laser, the method comprising:
forming a workpiece piece on a first planar region film provided on the light emitting layer, the workpiece including a first region;
removing a part of the workpiece form a recessed, a part of the first planar region film and a side face of the first region being exposed in the recess;
forming a crystal film on the part of the first planar region film, the side face of the first region, and the first region being remained; and
forming a first crystal layer in a remaining space of the recess,
a concentration of the first element in the first crystal layer being higher than a concentration of the first element in the crystal film, or the first crystal layer including the first element and the crystal film not including the first element, and
a refractive index of the first region being higher than a refractive index of the first crystal layer.

### (Technical Proposal 20)

The method for manufacturing the surface emitting laser according to Technical proposal 19, wherein
the first crystal layer includes InP, and
the first element includes at least one selected from the group consisting of Si and Fe.

According to the embodiment, a surface emitting laser whose characteristics can be improved and a method for manufacturing the same can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in surface emitting lasers such as electrodes, light emitting layers, crystal layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all surface emitting lasers and all methods for manufacturing the same practicable by an appropriate design modification by one skilled in the art based on the surface emitting lasers and the methods for manufacturing the same described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A surface emitting laser, comprising:
a first electrode;
a second electrode;
a light emitting layer provided between the first electrode and the second electrode;
a first crystal layer provided between the light emitting layer and the second electrode, the first crystal layer including a first partial region and a second partial region; and
a second crystal layer including a plurality of structures, at least a part of the plurality of structures being arranged in a second direction crossing a first direction from the first electrode to the second electrode, the plurality of structures being provided between the light emitting layer and the first partial region in the first direction, at least a part of the second partial region being provided between the plurality of structures in the second direction, one of the plurality of structures includes a first region and a second region provided between the first region and the first partial region, a concentration of a first element in the second partial region being higher than a concentration of the first element in the second region, or the second partial region including the first element and the second region not including the first element, a refractive index of the first region being higher than a refractive index of the second partial region.

2. The surface emitting laser according to claim 1, wherein
the first crystal layer includes InP, and
the first element includes at least one selected from the group consisting of Si and Fe.

3. The surface emitting laser according to claim 2, wherein
the first region includes InGaAs, and
the second region includes InP.

4. The surface emitting laser according to claim 1, wherein
an electrical conductivity of the second region is lower than an electrical conductivity of the second partial region.

5. The surface emitting laser according to claim 4, wherein
the second crystal layer further includes a first planar region,
the first region is provided between a part of the first planar region and the second region, and
the second partial region is provided between another part of the first planar region and the second electrode.

6. The surface emitting laser according to claim 5, wherein
a concentration of the first element in the first planar region is higher than the concentration of the first element in the second region, or the first planar region includes the first element and the second region does not include the first element.

7. The surface emitting laser according to claim 5, wherein
the one of the plurality of structures further includes a third region,
the third region is provided between the first planar region and the first region,
a concentration of the first element in the third region is lower than the concentration of the first element in the second partial region, or the second partial region includes the first element and the third region does not include the first element.

8. The surface emitting laser according to claim 7, wherein
a third thickness of the third region along the first direction is not less than 100 nm and not more than 300 nm.

9. The surface emitting laser according to claim 1, wherein
a concentration of the first element in the first region is higher than the concentration of the first element in the second region or the first region includes the first element and the second region does not include the first element.

10. The surface emitting laser according to claim 1, wherein
a second thickness of the second region along the first direction is thinner than a first thickness of the first region along the first direction.

11. The surface emitting laser according to claim 10, wherein
the second thickness is not less than 100 nm and not more than 300 nm, and
the first thickness is not less than 500 nm and not more than 1500 nm.

12. The surface emitting laser according to claim 1, wherein
the one of the plurality of structures further includes a fourth region,
the fourth region is provided between the second partial region and the first region in the second direction,
the concentration of the first element in the second partial region is higher than a concentration of the first element in the fourth region, or the second partial region includes the first element and the fourth region does not include the first element.

13. The surface emitting laser according to claim 12, wherein
the fourth region is continuous with the second region.

14. The surface emitting laser according to claim 1, further comprising:
a first cladding layer provided between the first electrode and the light emitting layer,
the light emitting layer being provided between a part of the first cladding layer and the second crystal layer.

15. The surface emitting laser according to claim 1, wherein
the light-emitting layer emits light by inter-subband transition.

16. A method for manufacturing a surface emitting laser, the method comprising:
forming a workpiece on a first planar region film provided on a light emitting layer, the workpiece including a first region and a second region above the first region;
removing a part of the workpiece to expose a part of the first planar region film to form a recess; and
forming a first crystal layer in the recess and on the second region,
a concentration of the first element in the first crystal layer being higher than a concentration of the first element in the second region, or the first crystal layer including the first element and the second region not including the first element, and
a refractive index of the first region being higher than a refractive index of the first crystal layer.

17. The method for manufacturing the surface emitting laser according to claim 16, wherein
the first crystal layer includes InP, and
the first element includes at least one selected from the group consisting of Si and Fe.

18. The method for manufacturing the surface emitting laser according to claim 16, wherein
the workpiece further includes a third region provided between the first planar region film and the first region, and
a concentration of the first element in the third region is higher than the concentration of the first element in the first crystal layer, or the first crystal layer includes the first element and the third region does not include the first element.

19. A method for manufacturing a surface emitting laser, the method comprising:
forming a workpiece piece on a first planar region film provided on the light emitting layer, the workpiece including a first region;
removing a part of the workpiece form a recessed, a part of the first planar region film and a side face of the first region being exposed in the recess;
forming a crystal film on the part of the first planar region film, the side face of the first region, and the first region being remained; and
forming a first crystal layer in a remaining space of the recess,
a concentration of the first element in the first crystal layer being higher than a concentration of the first element in the crystal film, or the first crystal layer including the first element and the crystal film not including the first element, and
a refractive index of the first region being higher than a refractive index of the first crystal layer.

20. The method for manufacturing the surface emitting laser according to claim 19, wherein
the first crystal layer includes InP, and
the first element includes at least one selected from the group consisting of Si and Fe.
